(19) United States
(12) Patent Application Publication
(10) Pub. No.: US 2023/0348207 A1
(43) Pub. Date: Nov. 2, 2023

(54) TRANSFER PLATE SET AND SUBSTRATE TRANSFER APPARATUS

(71) Applicant: SEMES CO., LTD., Cheonan-si (KR)

(72) Inventors: Dukhyun SON, Cheonan-si (KR); Jae-won SHIN, Seoul (KR)

(73) Assignee: SEMES CO., LTD., Cheonan-si (KR)

(21) Appl. No.: 18/141,411

(22) Filed: Apr. 29, 2023

(30) Foreign Application Priority Data
May 2, 2022 (KR) 10-2022-0054243

(51) Int. Cl. B65G 47/90; H01L 21/677

(52) U.S. Cl. CPC B65G 47/90; H01L 21/67706; H01L 21/67709; H01L 21/67742

(57) ABSTRACT

Disclosed is a transfer plate set. More particularly, the transfer plate set serves to guide a substrate transfer unit to move, the transfer plate set including a first plate part; and a second plate part inserted and fixed to the first plate part, wherein the first plate part includes a first base; a first guide member disposed on the first base; and a receiving part formed to be stepped on a side facing the second plate part, and wherein the second plate part includes a second base; a second guide member disposed on the second base; and an insertion part formed to protrude from a side facing the first plate part and provided to be inserted into the receiving part.

### CROSS-REFERENCE TO RELATED APPLICATION

This application claims priority to and the benefit of Korean Patent Application No. 10-2022-0054243, filed on May 2, 2022, the disclosure of which is incorporated herein by reference in its entirety.

### BACKGROUND OF THE INVENTION

### 1. Field of the Invention

The present disclosure relates to a semiconductor apparatus, and more particularly to a transfer plate set and a substrate transfer apparatus.

### 2. Description of the Related Art

To fabricate semiconductor devices, a substrate is subject to various processes such as photolithography, etching, ashing, ion implantation, deposition, and cleaning. To perform these processes, various substrate processing apparatuses are used. The substrate should be transferred to an execution position of each of various processes in the course of being treated by the processes, which is performed by a substrate transfer apparatus. The substrate transfer apparatus is an automated facility that transfers a substrate to the execution position of each process according to a predetermined program.

Meanwhile, as semiconductor devices increase in performance and substrates become larger in diameter, the size of semiconductor facilities tends to increase, and a plurality of substrate processing apparatuses are arranged horizontally and vertically in a facility to increase productivity. Corresponding to an increase in the size of semiconductor facilities, an area in which the substrate transfer apparatus moves also widens.

A driving shaft needs to be extended longer to move a substrate transfer apparatus over a wider area. Accordingly, a technique for constituting a long-extended driving shaft by connecting a plurality of modularized driving shafts is desirable. In addition, in the process of lengthening driving shafts, a technology for precisely aligning and connecting the driving shafts is desirable. However, since plates, which are supported by the driving shafts, have a size of tens to hundreds of cm and are manufactured on a large scale to the extent of having a weight in tons, it is difficult to precisely align the driving shafts. In addition, there is also a problem in that particles are generated due to friction between plates in the process of connecting the driving shafts.

### SUMMARY OF THE INVENTION

Therefore, the present disclosure has been made in view of the above problems, and it is an object of the present disclosure to provide a transfer plate set and substrate transfer apparatus that allow the connection of a plurality of driving shafts along which a substrate transfer unit moves.

It is another object of the present disclosure to provide a transfer plate set and substrate transfer apparatus that allow the precise alignment and connection of the driving shafts.

It is yet another object of the present disclosure to provide a transfer plate set and substrate transfer apparatus capable of minimizing the generation of particles in the process of connecting the driving shafts.

It will be understood that the technical problems are only provided as examples, and the scope of the present disclosure is not limited thereto.

In accordance with an aspect of the present disclosure, the above and other objects can be accomplished by the provision of a transfer plate set for guiding a substrate transfer unit to move, the transfer plate set including: a first plate part; and a second plate part inserted and fixed to the first plate part, wherein the first plate part includes a first base; a first guide member disposed on the first base; and a receiving part formed to be stepped on a side facing the second plate part, and wherein the second plate part includes a second base; a second guide member disposed on the second base; and an insertion part formed to protrude from a side facing the first plate part and provided to be inserted into the receiving part.

In the transfer plate set, upper and lower surfaces of the insertion part may be formed parallel to a horizontal direction.

In the transfer plate set, first protrusions may be formed on upper and lower surfaces of the insertion part.

In the transfer plate set, corners of the first protrusions may be formed to be rounded.

In the transfer plate set, the first protrusions may be formed in a width direction perpendicular to a longitudinal direction of the insertion part.

In the transfer plate set, a sum of a height of the insertion part and heights of the first protrusions may correspond to a height of the receiving part.

In the transfer plate set, second protrusions may be formed on left and right surfaces of the insertion part in a longitudinal direction.

In the transfer plate set, corners of the second protrusions may be formed to be rounded.

In the transfer plate set, the second protrusions may be formed in a direction parallel to a height direction of the insertion part.

In the transfer plate set, the insertion part may have a shape in which a width of the insertion part gradually increases and then decreases to correspond to a width of the receiving part as approaches from one side of the insertion part opposite to the receiving part to another side opposite to the one side of the insertion part.

In the transfer plate set, a fixture may be formed to penetrate the insertion part in a thickness direction.

In the transfer plate set, a fixing pin may be installed at a position, which corresponds to the fixture, on the receiving part, the fixture may have a size equal to or larger than the fixing pin, and when the insertion part is inserted into the receiving part, at least a portion of the fixing pin may enter the fixture.

In the transfer plate set, connecting holes may be formed to penetrate the insertion part in a thickness direction, and fastening grooves may be formed at positions, which correspond to the connecting holes, on the receiving part such that the connecting holes and the fastening grooves are mutually connected through connecting members.

In the transfer plate set, when the insertion part is inserted and fixed to the receiving part, the receiving part and the first protrusions of the insertion part may come into point contact or line contact.

In the transfer plate set, the first plate part may further include a cover part for covering an upper part of the receiving part, when the insertion part is inserted and fixed to the receiving part, the insertion part may be disposed in an insertion space formed by a step of the receiving part and the cover part, and a rotational pitch PI in a vertical direction of a horizontal axis of the insertion part may be controlled by a height difference between the upper or lower surface of the insertion part and the first protrusions in a process in which the insertion part is inserted into the receiving part.

In the transfer plate set, when the insertion part is inserted and fixed to the receiving part, a side surface of the receiving part and the second protrusions of the insertion part may come into point contact or line contact.

In the transfer plate set, a rotational yaw in a horizontal direction of a horizontal axis of the insertion part may be controlled by a difference between a width of an end of the insertion part and a width of the second protrusions in a process in which the insertion part is inserted into the receiving part.

In accordance with another aspect of the present disclosure, there is provided a substrate transfer apparatus, including: a transfer chamber to which at least one substrate processing apparatus for processing a substrate is coupled; a substrate transfer unit installed inside the transfer chamber and configured to support a substrate to load or unload the substrate into or from the substrate processing apparatus; and a transfer plate configured to guide the substrate transfer unit to move inside the transfer chamber, wherein the transfer plate includes a first plate part; and a second plate part inserted and fixed to the first plate part, wherein the first plate part includes a first guide member disposed on the first plate part; and a receiving part formed to be stepped on a side facing the second plate part, the second plate part includes a second guide member disposed on the second plate part; and an insertion part formed to protrude from a side facing the first plate part and provided to be inserted into the receiving part, first protrusions are formed on upper and lower surfaces of the insertion part, and second protrusions are formed on left and right surfaces with respect to a longitudinal direction of the insertion part, and the substrate transfer unit is installed to be movable along the first guide member and the second guide member.

In the substrate transfer apparatus, an upper part of the receiving part may be covered by a cover part, a sum of a height of the insertion part and heights of the first protrusions may correspond to a height of the receiving part, and when the insertion part is inserted and fixed to the receiving part, the insertion part may be disposed in an insertion space formed by a step of the receiving part and the cover part.

In accordance with yet another aspect of the present disclosure, there is provided a transfer plate set for manufacturing a transfer plate, the transfer plate set guiding a substrate transfer unit for loading or unloading a substrate into or from a substrate processing apparatus to move, wherein the transfer plate set includes a first plate part; and a second plate part inserted and fixed to the first plate part, wherein the first plate part includes a first guide member disposed on the first plate part; and a receiving part formed to be stepped on a side facing the second plate part, the second plate part includes a second guide member disposed on the second plate part; and an insertion part formed to protrude from a side facing the first plate part and provided to be inserted into the receiving part, first protrusions having rounded corners are formed on upper and lower surfaces of the insertion part, and second protrusions having rounded corners are formed on left and right surfaces with respect to a longitudinal direction of the insertion part, a sum of a height of the insertion part and heights of the first protrusions corresponds to a height of the receiving part, and when the insertion part is inserted and fixed to the receiving part, the receiving part and the first protrusions of the insertion part come into point contact or line contact, a side surface of the receiving part and the second protrusions of the insertion part come into point contact or line contact, and the first guide member of the first plate part and the second guide member of the second plate part are aligned on the same axis.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a schematic plan view illustrating a substrate processing facility according to an embodiment of the present disclosure;

FIG. 2 is a schematic perspective view illustrating a substrate transfer apparatus according to an embodiment of the present disclosure;

FIG. 3 is a schematic perspective view illustrating a transfer plate set according to an embodiment of the present disclosure;

FIG. 4 is a schematic sectional side view illustrating a portion of a receiving part and insertion part of the transfer plate set according to an embodiment of the present disclosure;

FIG. 5 is a schematic plan view illustrating a portion of the receiving part and insertion part of the transfer plate set according to an embodiment of the present disclosure;

FIG. 6 is a schematic sectional side view illustrating the connection of a transfer plate set according to a comparative example;

FIG. 7 is a schematic sectional side view illustrating the connection of a transfer plate set according to an embodiment of the present disclosure;

FIG. 8 is a schematic plan view illustrating the connection of a transfer plate set according to an embodiment of the present disclosure; and

FIG. 9 is a schematic plan view illustrating a process of continuously connecting transfer plate sets according to an embodiment of the present disclosure.

### DETAILED DESCRIPTION OF THE INVENTION

Hereinafter, one or more preferred embodiments of the present disclosure will be described in detail with reference to the accompanying drawings.

Embodiments of the present disclosure are provided to more completely explain the present disclosure to those skilled in the art, and the following embodiments may be modified in many different forms, but the scope of the present disclosure is not limited to the following embodiments. Rather, the embodiments are provided to make the disclosure thorough and complete and to fully convey the technical idea of the disclosure to those skilled in the art. In the drawings, the thicknesses and sizes of layers may be exaggerated for convenience and clarity of explanation.

Embodiments of the disclosure are described herein with reference to drawings that schematically illustrate idealized embodiments of the disclosure. As such, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing.

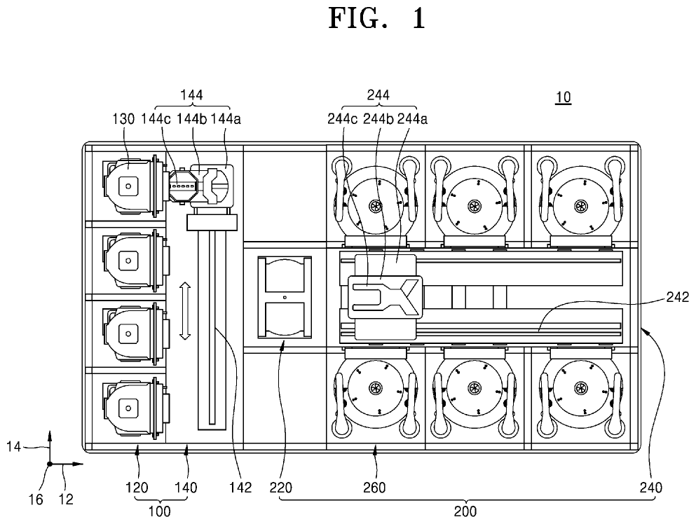

FIG. 1 is a schematic plan view illustrating a substrate processing facility 10 according to an embodiment of the present disclosure.

Referring to FIG. 1, the substrate processing facility 10 includes an index module 100 and a process processing module 200. The index module 100 includes load ports 120 and a transfer frame 140. The load ports 120, the transfer frame 140, and the process processing module 200 may be sequentially arranged. In this specification, a direction in which the load ports 120, the transfer frame 140 and the process processing module 200 are arranged is referred to as a first direction 12 (or x-axis direction), a direction perpendicular to the first direction 12 when viewed from above is referred to as a second direction 14 (or y-axis direction), and a direction perpendicular to a plane (xy plane) including the first and second directions 12 and 14 is referred to as a third direction 16 (or z-axis direction).

Carriers 130 in which substrates W are accommodated are seated in the load ports 120. The plural load ports 120 may be disposed along the second direction 14. The number of the load ports 120 may increase or decrease according to process efficiency, production efficiency, and the like of the process processing module 200. Front Opening Unified Pods (FOUPs) may be used as the carriers 130, and slots for horizontally accommodating the plural substrates W may be formed inside the carriers 130.

The process processing module 200 includes a buffer unit 220, a transfer chamber 240, and process chambers 260. The transfer chamber 240 extends parallel to the first direction 12, and the process chambers 260 may be disposed on opposite sides of the transfer chamber 240 in a longitudinal direction thereof In addition, some of the process chambers 260 may be stacked. Meanwhile, the process chambers 260 may be disposed only on one side of the transfer chamber 240.

The buffer unit 220 is disposed between the transfer frame 140 and the transfer chamber 240 and provides a space where the substrates W stay before being transferred to the transfer frame 140 or the transfer chamber 240. Slots where the substrates W are to be disposed are formed inside the buffer unit 220. The buffer unit 220 may be formed to be open or openable with respect to the transfer frame 140 and the transfer chamber 240.

The transfer frame 140 may serve the substrates W to transport between the carriers 130 and the buffer unit 220. The transfer frame 140 includes an index rail 142 and an index robot 144. The index rail 142 may extend in parallel to the second direction 14, and the index robot 144 may be installed thereon to move along the second direction 14. The index robot 144 includes a base 144a, a body 144b, and index arms 144c. The base 144a is installed to be movable along the index rail 142. The body 144b is coupled to the base 144a and installed on the base 144a to be movable and rotatable along the third direction 16. The index arms 144c are coupled with the body 144b and are provided to move forward and backward with respect to the body 144b.

A plurality of index arms 144c may be provided and individually driven. Each of the index arms 144c may be used when transferring the substrates W from the carriers 130 to the process processing module 200 or from the process processing module 200 to the carriers 130.

The transfer chamber 240 may serve the substrates W to transfer between the buffer unit 220 and the process chambers 260 or between the process chambers 260. The transfer chamber 240 includes a guide rail 242 and a main robot 244. The guide rail 242 may extend parallel to the first direction 12 and the main robot 244 is installed thereon to move along the first direction 12. The main robot 244 includes a base 244a, a body 244b and main arms 244c. The base 244a is installed to be movable along the guide rail 242. The body 244b is coupled to the base 244a and is installed on the base 244a to be movable and rotatable along the third direction 16. The main arms 244c are coupled to the body 244b and provided to move forward and backward with respect to the body 244b. A plurality of main arms 244c may be provided and individually driven.

The process chambers 260 includes substrate processing apparatuses for processing the substrates W. The substrate processing apparatuses may have different structures depending on a process to be performed. Meanwhile, substrate processing apparatuses in each of the process chambers 260 may have the same structure, and substrate processing apparatuses in the process chambers 260 belonging to the same group may have the same structure. By the substrate processing apparatuses, a liquid processing process, cleaning process, etching process, photolithography process, and the like on a substrate may be performed.

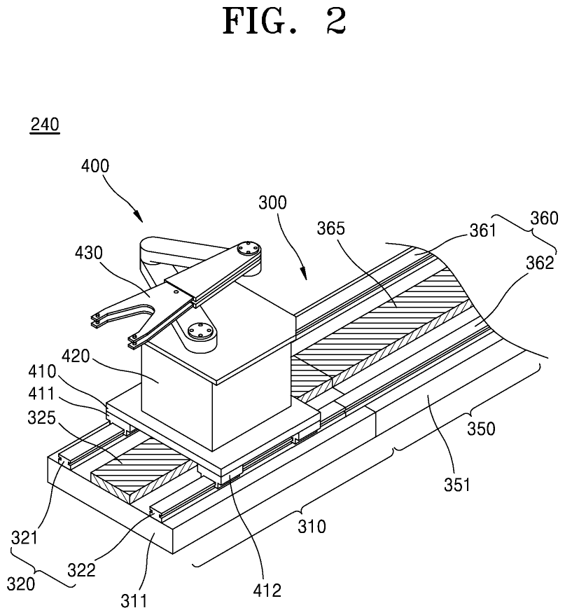

FIG. 2 is a schematic perspective view illustrating a substrate transfer apparatus 240 according to an embodiment of the present disclosure. The substrate transfer apparatus 240 corresponds to the transfer chamber 240 of FIG. 1. The substrate transfer apparatus 240 (or the transfer chamber 240) may include a transfer plate 300, a substrate transfer unit 400 and a frame. The substrate transfer unit 400 corresponds to the main robot 244 of FIG. 1. In FIG. 2, the illustration of a frame connected to the process chambers 260 is omitted, and only the transfer plate 300 and the substrate transfer unit 400 are only shown for convenience of explanation.

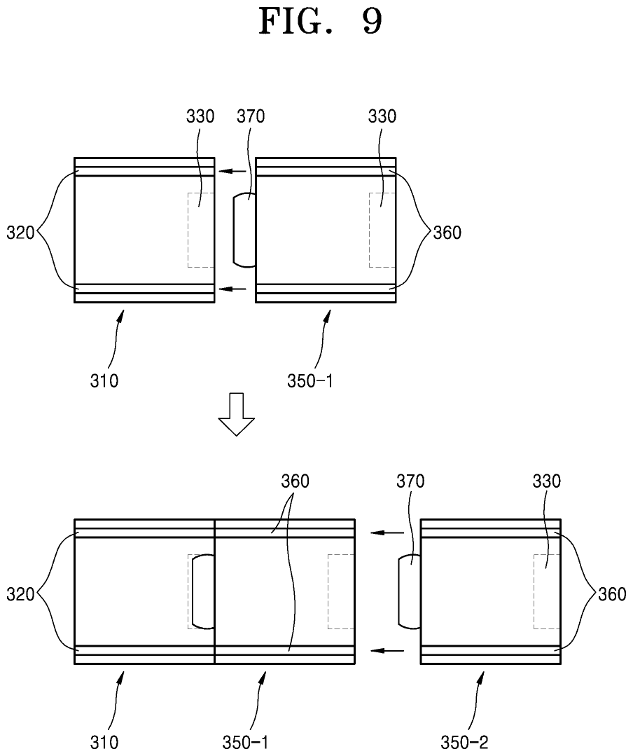

Referring to FIG. 2, the transfer plate 300 may include a plurality of plate parts 310 and 350. Although FIG. 2 illustrates an embodiment wherein two plate parts, i.e., the first plate part 310 and the second plate part 350 are connected to each other to form the transfer plate 300, two or more plate parts may be connected to each other to constitute the transfer plate 300 (see FIG. 9).

The transfer plate 300 is provided to include guide members 320 (321, 322) and 360 (361, 362). The guide members 320 and 360 may serve as rails providing a path along which the substrate transfer unit 400 moves. A longitudinal direction of the guide members 320 and 360 may be the first direction 12. The guide members 320 and 360 may be provided as a pair (321 and 322) or (361 and 362).

The first plate part 310 includes a first base 311; and a first guide member 320 (321, 322) disposed on the first base 311. The first base 311 is provided in a plate shape and constitutes a body of the first plate part 310. The first base 311 may be provided in the form of a single plate or by combining a plurality of plates. In addition, a linear motor 325 configured to provide a driving force for moving the substrate transfer unit 400 may be installed on the first base 311.

In addition, a cooling plate (not shown) may be provided in the first base 311 or on a side surface of the first base 311. Inside the cooling plate, a flow path through which cooling water such as process cooling water (PCW) flows is provided, thereby being capable of controlling the temperature of the substrate transfer unit 400, for example, the surface temperature and internal temperature of the substrate transfer unit 400.

A first linear motor 325 is composed of a stator and a mover. The stator may be provided with a magnet (permanent magnet), and the mover may be provided with an electromagnet. When current is supplied to the electromagnet, a thrust is generated between the electromagnet and a plurality of permanent magnets, so that a transfer base 410 of the substrate transfer unit 400 may be transferred to a designated position.

The second plate part 350 includes a second base 351; and a second guide member 360 (361, 362) disposed on the second base 351. The second base 351 is provided in a plate shape and constitutes a body of the second plate part 350. The second base 351 may be provided in the form of a single plate or by combining a plurality of plates.

In addition, a cooling plate (not shown) may be provided in the second base 351 or on a side surface of the second base 351. Inside the cooling plate, a flow path through which cooling water such as process cooling water (PCW) flows is provided, thereby being capable of controlling the temperature of the substrate transfer unit 400, for example, the surface temperature and internal temperature of the substrate transfer unit 400.

A second linear motor 365 is composed of a stator and a mover. The stator may be provided with a magnet (permanent magnet), and the mover may be provided with an electromagnet. When current is supplied to the electromagnet, a thrust is generated between the electromagnet and a plurality of permanent magnets, so that a transfer base 410 of the substrate transfer unit 400 may be transferred to a designated position.

The first linear motor 325 and the second linear motor 365 are provided to be interconnected.

The substrate transfer unit 400 is provided to transfer the substrates W (e.g., wafers) and may be implemented as a transfer robot. The substrate transfer unit 400 may be installed on the guide members 320 and 360. The substrate transfer unit 400 may linearly move on the guide members 320 and 360 along the first direction 12 in a state in which the substrate W is loaded.

The substrate transfer unit 400 may include a transfer base 410, a transfer body 420 and an arm member 430. The transfer base 410 may be provided in the form of a flat plate and may be disposed under the substrate transfer unit 400. The transfer base 410 may be installed to be movable in the first direction 12 along the guide members 320 and 360.

The transfer base 410 may be installed on a plurality of support blocks 411 and 412. As an embodiment, the transfer base 410 may be disposed on four support blocks disposed at predetermined intervals in the first direction 12 and the second direction 14. The transfer base 410 may have a channel therein to electrically connect the support blocks 411 and 412 and the linear motors 325 and 365 to each other.

The transfer body 420 may constitute a body of the substrate transfer unit 400 and may be coupled and installed on the transfer base 410. The transfer body 420 may be installed to support the arm member 430.

The arm member 430 is provided to load and unload the substrate W. The arm member 430 may be provided to move forward, backward, and rotate on the transfer body 420. In addition, the arm member 430 may be provided to be movable up and down in the third direction 16. One or plural arm members 430 may be installed on the transfer body 420 and may be individually driven.

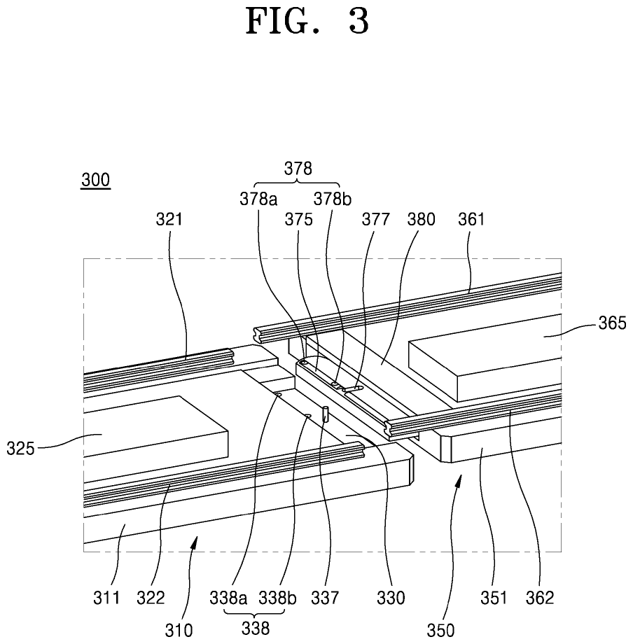

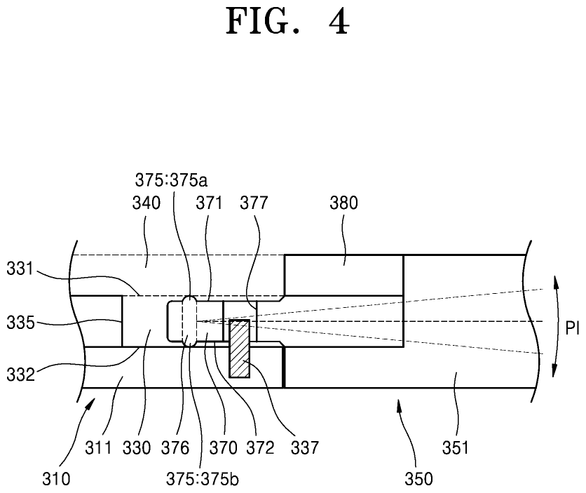

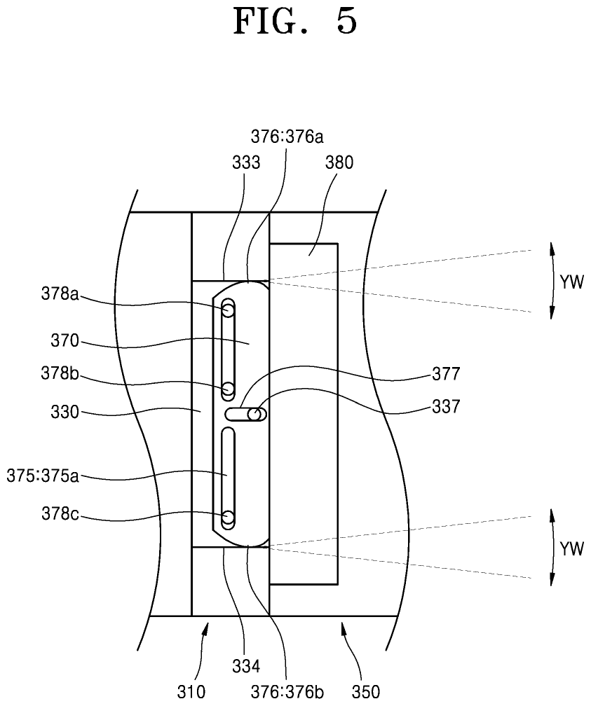

FIG. 3 is a schematic perspective view illustrating a transfer plate set 300 (310, 350) according to an embodiment of the present disclosure. FIG. 4 is a schematic sectional side view illustrating a portion of a receiving part 330 and insertion part 370 of the transfer plate set 300 according to an embodiment of the present disclosure. FIG. 5 is a schematic plan view illustrating a portion of the receiving part 330 and insertion part 370 of the transfer plate set 300 according to an embodiment of the present disclosure. FIGS. 4 and 5 illustrate a state in which the first plate part 310 and second plate part 350 of the transfer plate set 300 are in close contact, i.e., a state in which the insertion part 370 is inserted and accommodated in the receiving part 330.

Referring to FIG. 3, the transfer plate set 300 (310, 350) may include the first plate part 310 and the second plate part 350. The first plate part 310 and the second plate part 350 may be provided as separate modules. When the first plate part 310 and the second plate part 350 are engaged with each other, the transfer plate set 300 (310, 350) of FIG. 3 may be provided as the transfer plate 300 of FIG. 2. Although the transfer plate set 300 constituted of the two modules, i.e., the first plate part 310 and the second plate part 350, is provided as an embodiment in FIGS. 2 and 3, the number of the plate parts may be two or more.

In accordance with an embodiment, the first plate part 310 may be constituted to include the receiving part 330 and the second plate part 350 may be constituted to include the insertion part 370, i.e., the first and second plate parts 310 may be constituted to have different configurations.

In accordance with another embodiment, the first plate part 310 and the second plate part 350 may be constituted to have the same configuration. For example, the first plate part 310 may be constituted to include the receiving part 330 on one side thereof and the insertion part 370 on an opposite side thereof, and the second plate part 350 may be constituted to include the insertion part 370 on one side thereof and the receiving part 330 on opposite side thereof. Accordingly, the first plate part 310, the second plate part 350, a third plate part (not shown), and the like may be continuously engaged to constitute the transfer plate 300 (see FIG. 9).

The first plate part 310 may be provided to include the receiving part 330. The second plate part 350 may be provided to include the insertion part 370. As the insertion part 370 of the second plate part 350 is inserted into and fixed to the receiving part 330 of the first plate part 310, the first plate part 310 and the second plate part 350 may be connected to each other.

In the first plate part 310, the receiving part 330 may be formed to be stepped on a side facing the second plate part 350. That is, the receiving part 330 may correspond to a stepped space in the first plate part 310 to accommodate the insertion part 370. As the receiving part 330 is formed, upper and lower surfaces 331 and 332 (see FIG. 4], front surface (reference numeral not shown), rear surface 335 (see FIG. 4), and left and right surfaces 333 and 334 (see FIG. 5) of the receiving part 330 may be defined. In some embodiments, the receiving part 330 may include a stepped portion defining an empty space that is defined by the lower surface 332, the rear surface 335, and the left and right surfaces 333 and 334. In some embodiments, the receiving part 330 may correspond to a recess formed at a first side of the first base 311. The recess is defined by the lower surface 332 (i.e., a bottom surface of a recess portion), the rear surface 335 (i.e., a rear surface of the recessed portion), and the left and right surfaces 333 and 334 (i.e., left and right surfaces of the recessed portion). The present disclosure is not limited thereto. For example, the empty space of the receiving part 330 may be defined by two or more plates that configured to form the stepped portion of the receiving part 330 as shown in FIGS. 4 and 5.

A cover part 340 may be further included on the receiving part 330. The cover part 340 may cover an upper surface 331 of the receiving part 330. The cover part 340 is preferably installed on the top of the first plate part 310 after the first plate part 310 and the second plate part 350 are engaged with each other, but may be installed before the engagement. In a state where the cover part 340 is covered on the receiving part 330, the receiving part 330 is provided to be opened only in a front direction.

In the second plate part 350, the insertion part 370 may be formed to protrude from a side facing the first plate part 310. That is, the insertion part 370 may protrude to be inserted into the receiving part 330.

Here, various embodiments of a form in which the insertion part 370 is inserted into the receiving part 330 include a form in which the second plate part 350 enters and is inserted on the same horizontal plane along the first direction 12, a form in which the second plate part 350 enters the first direction 12 at a mutually spaced height along the third direction 16 and then is inserted while moving downward, a form in which the second plate part 350 is inserted while moving along a combination of the first direction 12 and the third direction 16, and the like. As another embodiment, when the cover part 340 is installed on the receiving part 330, the insertion part 370 of the second plate part 350 may be inserted in an open front direction of the receiving part 330.

Referring to FIGS. 3 to 5, a fixing pin 337 may be installed on the receiving part 330. The fixing pin 337 may be formed to extend substantially along the third direction 16 and may be integrated with or detachably installed in the first base 311. In addition, a fixture 377 may be formed to pass through the insertion part 370 in a thickness direction. The fixture 377 may be formed at a position of the insertion part 370 corresponding to the fixing pin 337.

During an engagement process of the first plate part 310 and the second plate part 350, a part of the fixing pin 337 may enter the fixture 377 of the insertion part 370. The fixing pin 337 may be fixed within the fixture 377, or the fixture 377 may be partially movable relative to the fixing pin 337. That is, the size of the fixture 377 may be equal to or larger than the size of the fixing pin 337. Accordingly, the fixing pin 337 and the fixture 377 may play a role of primarily fixing the first plate part 310 and the second plate part 350 not to get out of alignment during the engagement process.

As an embodiment, in the case that the second plate part 350 enters from the same horizontal plane along the first direction 12, the fixing pin 337 may be installed in the receiving part 330 to perform fixing primarily when the insertion part 370 enters the receiving part 330 and the fixture 377 where the fixing pin 337 is to be installed is aligned. As another embodiment, in the case that the second plate part 350 moves downward after entering in the first direction 12 at a mutually spaced height along the third direction 16, the fixing pin 337 installed on the receiving part 330 is matched with the axis position of the third direction 16 of the fixture 377 of the insertion part 370 before the second plate part 350 moves downward, and then the second plate part 350 moves downward so that the fixing pin 337 enters the fixture 377, thereby performing primary fixation.

In accordance with an embodiment, the fixture 377 may be formed to penetrate the insertion part 370 along the third direction 16 and, at the same time, to have a larger width, in the first direction 12, than the fixing pin 337. The width of the fixture 377 in the second direction 14 may be the same as the fixing pin 337. In this case, when the fixing pin 337 enters the fixture 377, the fixture 377 can flow only in the first direction 12 due to the engagement of the fixing pin 337. That is, in the process of inserting the insertion part 370 (or the second plate part 350) into the receiving part 330, the movement of the insertion part 370 in the second direction 14 may be restricted. Accordingly, a rotational yaw (YW) of the insertion part 370, i.e., only a rotational angle (YW) on a plane in the direction in which the insertion part 370 enters the receiving part 330 along the first direction 12, may be only considered.

Fastening grooves 338 (338a, 338b, 338c) may be formed on the receiving part 330. In this specification, the number of the fastening grooves 338 is exemplified as three, but the number is not limited thereto. In addition, connecting holes 378 (378a, 378b, 378c) may be formed on the insertion part 370 to penetrate the insertion part 370 in the thickness direction thereof. The connecting holes 378 (378a, 338b, 378c) may be formed at positions of the insertion part 370 that correspond to the positions of the fastening grooves 338 (338a, 338b, 338c).

During the engagement process of the first plate part 310 and the second plate part 350, the fixing pin 337 enters the fixture 377 to be primarily fixed, and, after contact/alignment of the first plate part 310 and the second plate part 350 is completed, secondary fixation may be performed between the fastening grooves 338 and the connecting holes 378 by interposing a connecting member such as a bolt.

The insertion part 370 may be disposed on the second base 351. A protruding connector 380 may be connected to a portion of the second base 351 excluding the protruding portion of the insertion part 370 so that the insertion part 370 can be fixed on the second base 351. In accordance with an embodiment, after the first plate part 310 and the second plate part 350 are engaged, the heights of upper surfaces of the cover part 340 and the protruding connector 380 can be set equal.

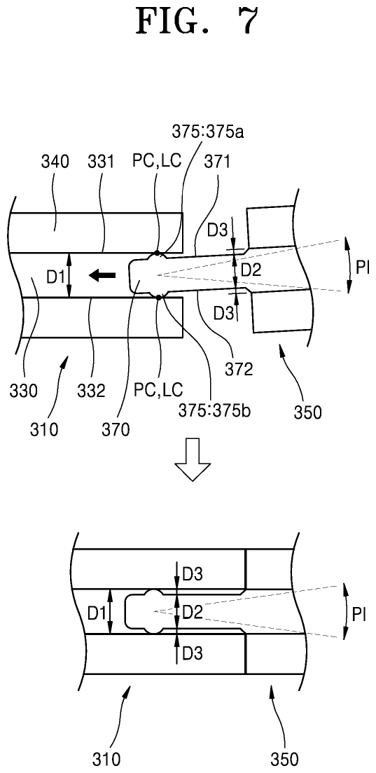

In accordance with an embodiment, the insertion part 370 may have an upper surface 371 and a lower surface 372 that are parallel to the horizontal direction (the first direction 12 and the second direction 14). In addition, first protrusions 375 (375a, 375b) may be formed on the upper surface 371 and lower surface 372 of the insertion part 370. The insertion part 370 on which the first protrusions 375 are formed may be inserted into the receiving part 330. The sum of a height D2 of the insertion part 370 in the third direction 16 and a height D3 of the first protrusions 375 may correspond to a height D1 of the receiving part 330 (see FIG. 7).

Corners of the first protrusions 375 (375a, 375b) may be formed to be rounded. FIG. 4 shows first protrusions 375 whose side section shape is a semicircle, but the side cross-section shape of the first protrusions 375 is not limited so long as it is a half-ellipse or has other curvature.

In accordance with an embodiment, the first protrusions 375 may be formed along a width direction (the second direction 14) perpendicular to a longitudinal direction (the first direction 12) on the insertion part 370. One of the first protrusions 375 may be formed to extend along the width direction, or the plural first protrusions 375 may be formed to have small-diameter intervals along the width direction. A length in the width direction of the first protrusions 375 is not limited. As an embodiment, FIGS. 3 to 5 illustrate that two first protrusions 375a are formed symmetrically around the width direction on the upper surface of the insertion part 370. Considering this, the first protrusions 375 may be formed in a bar shape in a shape similar to a semi-cylindrical column on the insertion part 370. As another embodiment, the first protrusions 375 may be formed in the form of a spot in a shape similar to a semicircle on the insertion part 370.

Since the first protrusions 375 are formed to be rounded, only one point or line of the first protrusions 375 contacts a specific object when the first protrusions 375 come into contact with the specific object. That is, when the insertion part 370 having the first protrusions 375 is inserted into the receiving part 330, the first protrusion 375 makes point contact or line contact with the upper surface 331 and/or the lower surface 332. As an embodiment, when the first protrusions 375 are formed in the form of a spot in a shape similar to a semicircle on the insertion part 370, any one point of the first protrusions 375 may make point contact with the surface of the receiving part 330. As another embodiment, when the first protrusions 375 are formed in a bar shape in a shape similar to a semi-cylindrical column on the insertion part 370, the first protrusions 375 may make line contact with the surface of the receiving part 330. Naturally, point contact and line contact may be combined.

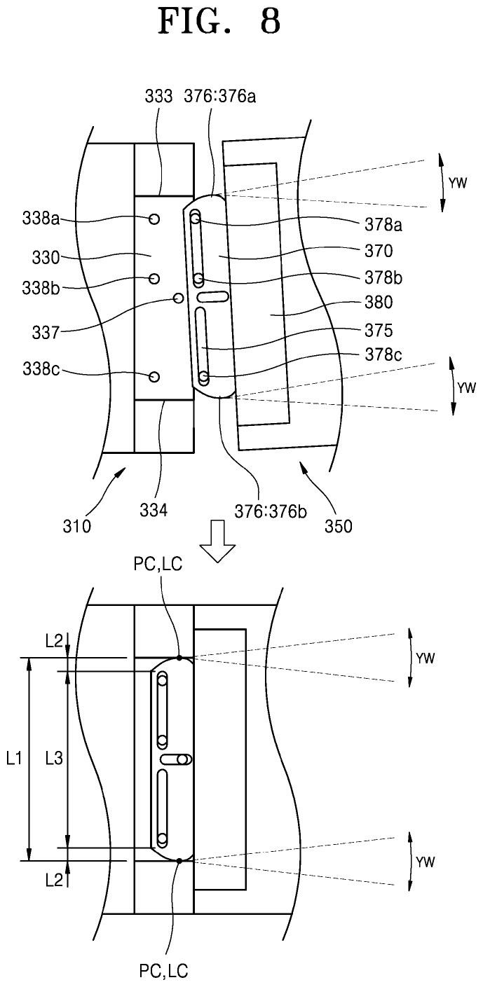

Referring to FIGS. 4 and 5, second protrusions 376 (376a, 376b) may be formed on left and right surfaces of the insertion part 370 based on a longitudinal direction (the first direction 12) of the insertion part 370. The insertion part 370 on which the second protrusions 376 are formed may be inserted into the receiving part 330. The sum of a width L3 in the second direction 14 of the insertion part 370 and a width L2 of second protrusions 376 may correspond to a width L1 of the receiving part 330 (see FIG. 8).

Corners of the second protrusions 376 (376a, 376b) may be formed to be rounded. FIG. 5 illustrates second protrusions 376 whose planar section shape is roughly a semi-arc, but the side cross-section shape of the second protrusions 376 is not limited so long as it is a half-circle or a half-ellipse or has other curvature.

In accordance with an embodiment, the second protrusions 376 may be formed along a direction parallel to the height direction (the third direction 16) on the left- and right-side surfaces of the insertion part 370. The second protrusions 376 may be formed to extend along the third direction 16, or the plural second protrusions 376 may be formed to have small-diameter intervals along the third direction 16. The length of the second protrusions 376 is not limited. As an embodiment, FIGS. 4 and 5 illustrate that two second protrusions 376 are formed on left- and right-side surfaces of the insertion part 370 along the third direction 16 to the same thickness as the insertion part 370. As another embodiment, the second protrusions 376 may be formed in the form of a plurality of spots having a predetermined interval on the left- and right-side surfaces of the insertion part 370 in a shape similar to a half-circle.

In accordance with another embodiment, the insertion part 370 may have a shape in which the width thereof gradually increases and then decreases from one side (front surface side) opposite to the receiving part 330 to an opposite side (rear surface side). Since the one side of the insertion part 370 is a first part to enter the receiving part 330, the width of the one side may be relatively narrow to easily enter between the left side 333 and right side 334 of the receiving part 330 without getting caught. In addition, the width gradually may increase as approaches the opposite side (rear surface side) and may increase up to a width corresponding to the left and right width of the receiving part 330, and the width may gradually decrease as further approaches the opposite side. Here, portions with the largest width on opposite sides of the insertion part 370 may act as the second protrusions 376. It is natural that the protruding parts may act as the second protrusions 376 so long as the protruding parts have a tapered shape based on a plane and include protruding parts corresponding to the left and right width of the receiving part 330, without necessarily being limited to the above shape.

Since the second protrusions 376 are formed to be rounded, only one point or line of the second protrusions 376 contacts a specific object when the second protrusions 376 come into contact with the specific object. That is, when the insertion part 370 having the second protrusions 376 is inserted into the receiving part 330, the second protrusions 376 makes point contact or line contact with the left surface 333 and/or the right surface 334. As an embodiment, when the second protrusions 376 are formed along the vertical direction to correspond to the thickness of the insertion part 370, the second protrusions 376 may make line contact with the surface of the receiving part 330. As another embodiment, when the second protrusions 376 are formed in a spot shape, any one point of the second protrusions 376 may come into point contact with the surface of the receiving part 330. Naturally, point contact and line contact may be combined.

Meanwhile, similar to the first protrusions 375 and the second protrusions 376, it is preferable that the corners of the insertion part 370 are rounded to prevent friction when entering the receiving part 330 and to allow easy entry.

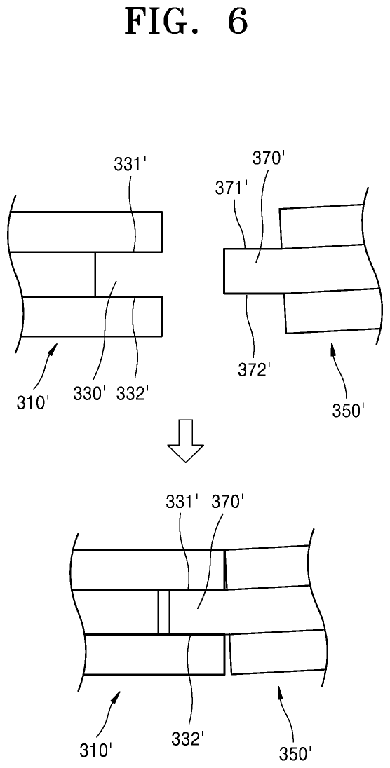

FIG. 6 is a schematic sectional side view illustrating the connection of a transfer plate set 300′(310′, 350′) according to a comparative example.

The transfer plate set 300′ according to a comparative example includes a first plate part 310′ and a second plate part 350′. The first plate part 310′ includes a receiving part 330′ as a female structure, and the second plate part 350′ includes an insertion part 370′ as a male structure. The receiving part 330′ and the insertion part 370′ may be manufactured to be engaged with each other. However, considering the size for mounting a substrate transfer apparatus that transfers wafers having a size of 300 mm or more, it is considered to manufacture the insertion part 370′ to have a length of about 50 mm or more in the first direction 12 and the second direction 14 to have a width of about 400 mm in the second direction 14. In addition, since the total weight of the second plate part 350′ may be hundreds of kg or more, processing errors may occur in detailed parts of a unit of mm or less.

Although shown somewhat exaggeratedly, even if a millimeter-level processing error occurs, there may occur a problem in the alignment of a guide rail (not shown) on the first plate part 310′ and the second plate part 350′ when insertion of the insertion part 370′ into the receiving part 330′ is completed, referring to the lower drawing of FIG. 6.

In addition, a protruding portion of the insertion part 370′ has a roughly rectangular parallelepiped shape. When a processing error occurs on either side of the rectangular parallelepiped shape, the alignment of other sides may be misaligned in the process in which the surface of the insertion part 370′ and the receiving part 330′ are in contact. For example, the lower surface 372′ of the insertion part 370′ and the lower surface 332′ of the receiving part 330′ are in snug surface contact, whereas the upper surface 371′ of the insertion part 370′ and the upper surface 331′ of the receiving part 330′ may not fit together and become twisted. When processing errors occur on the left and right surfaces as well as the upper and lower surfaces, the problem of twisting may occur as it is.

In addition, in the process of surface contact between the insertion part 370′ and the receiving part 330′, excessive fine particles may be generated due to friction, and these fine particles may contaminate the inside of a substrate transfer apparatus and a substrate processing facility.

Therefore, the present disclosure is characterized by proposing a structure in which the insertion part 370 and the receiving part 330 make point contact or line contact so as to address the above-described problem of the comparative example of FIG. 6. Hereinafter, a connection process of the first plate part 310 and the second plate part 350 is examined.

FIG. 7 is a schematic sectional side view illustrating the connection of a transfer plate set 300 (310, 350) according to an embodiment of the present disclosure. FIG. 8 is a schematic plan view illustrating the connection of a transfer plate set 300 (310, 350) according to an embodiment of the present disclosure.

First, referring to FIG. 7, an upper surface 331 of the receiving part 330 (or a lower surface of the cover part 340) and a lower surface 332 thereof may be in contact in a process in which the insertion part 370 enters the receiving part 330. Here, first protrusions 375 (375a, 375b) formed on upper and lower portions of the insertion part 370 may first contact the upper and lower surfaces 331 and 332 of the receiving part 330. The first protrusions 375 (375a, 375b) may guide the insertion part 370 to smoothly enter the receiving part 330 while making point contact (PC) or line contact (LC) with the upper and lower surfaces 331 and 332 of the receiving part 330. That is, since the contact between the insertion part 370 and the receiving part 330 is point-to-surface or line-to-surface contact, not surface-to-surface contact, smooth entry may be made with little friction.

In addition, due to a height difference D3 between the height of the first protrusions 375 (375a, 375b) and the upper surface 371 or lower surface 372 of the insertion part 370, distortion may be corrected as the insertion part 370 enters. In other words, in the insertion part 370, an empty space is formed due to the height difference D3 between an upper first protrusion 375a and the upper surface 371 or between a lower first protrusion 375b and the lower surface 372, and the space may function as a spare space for twisting.

For example, even if the insertion part 370 enters in a twisted state as shown in the upper drawing of FIG. 7, the receiving part 330 and the insertion part 370 are not immediately misaligned by the empty space secured by the height difference D3 and the insertion part 370 may further sufficiently enter while maintaining point contact or line contact. As the insertion part 370 is continuously inserted into the receiving part 330, a rotational pitch PI in a vertical direction of the horizontal axis of the insertion part 370, i.e., in a vertical direction with respect to one point of the axis of the first direction 12, may be controlled. Accordingly, the insertion part 370 is positioned and inserted into the receiving part 330 even if some processing errors occur in the insertion part 370, as shown in the lower drawing of FIG. 7.

Next, referring to FIG. 8, the insertion part 370 may contact a left side 333 and right side 334 of the receiving part 330 in the process of entering the receiving part 330. Here, second protrusions 376 (376a, 376b) formed on left- and right-side surfaces of the insertion part 370 may first contact the left and right surfaces 333 and 334 of the receiving part 330. The second protrusions 376 (376a, 376b) may guide the insertion part 370 to smoothly enter the receiving part 330 while making point contact (PC) or line contact (LC) with the left and right surfaces 333 and 334 of the receiving part 330. That is, since the contact between the insertion part 370 and the receiving part 330 is point-to-surface or line-to-surface contact, not surface-to-surface contact, smooth entry may be made with little friction.

In addition, due to a width difference L2 between the width of the second protrusions 376 (376a, 356b) and the width of an end (front end) of the insertion part 370, distortion may be corrected as the insertion part 370 enters. In other words, in the insertion part 370, an empty space is formed due to the width L2 between the width of the second protrusions 376 (376a, 356b) and the end (front end) of the insertion part 370, and the space may function as a spare space for twisting.

For example, even if the insertion part 370 enters in a twisted state as shown in the upper drawing of FIG. 8, the receiving part 330 and the insertion part 370 are not immediately misaligned by the empty space secured by the width difference L2 and the insertion part 370 may further sufficiently enter while maintaining point contact or line contact. As the insertion part 370 is continuously inserted into the receiving part 330, a rotational yaw YW in a horizontal direction of the horizontal axis of the insertion part 370, i.e., in a horizontal direction with respect to one point of the axis of the first direction 12, may be controlled. Accordingly, the insertion part 370 is positioned and inserted into the receiving part 330 even if some processing errors occur in the insertion part 370, as shown in the lower drawing of FIG. 8.

As described above, in the transfer plate set 300 (310, 350) of the present disclosure, the insertion part 370 may be inserted and fixed to the receiving part 330 in point contact or line contact with the receiving part 330. When the interconnection of the first plate part 310 and the second plate part 350 is completed, a first guide member 320 disposed on the first plate part 310 and a second guide member 360 disposed on the second plate part 350 may be aligned on the same axis.

FIG. 9 is a schematic plan view illustrating a process of continuously connecting transfer plate sets 300 (310, 350-1, 350-2) according to an embodiment of the present disclosure.

Referring to FIG. 9, a plurality of second plate parts 350-1 and 350-2 on which the insertion part 370 is formed may be provided. Each of the second plate parts 350-1 and 350-2 may include the receiving part 330 in addition to the insertion part 370.

First, the first plate part 310 and the second plate part 350-1 may be connected to each other. As the insertion part 370 of the second plate part 350-1 is inserted and fixed to the receiving part 330 of the first plate part 310, the first plate part 310 and the second plate part 350-1 may be connected to each other. Therefore, guide rails 320 and 360 may be aligned on the same axis.

Next, the second plate part 350-1 may be connected to another second plate part 350-2. As the insertion part 370 of the second plate part 350-2 is inserted and fixed to the receiving part 330 of the second plate part 350-1, the second plate part 350-1 and the second plate part 350-2 may be connected to each other. Therefore, guide rails 360 may be aligned on the same axis. By sequentially performing the process, a plurality of plate parts may be connected to each other, and the guide rails 320 and 360 which can guide the substrate transfer unit 400, may also be extended while aligning on the same axis.

As apparent from the above description, in accordance with an embodiment of the present disclosure, a plurality of driving shafts along which a substrate transfer unit moves can be connected.

In addition, in accordance with an embodiment of the present disclosure, contamination inside a substrate processing apparatus can be prevented and the occurrence of process defects can be improved by reducing the scattering of a substrate processing liquid.

In addition, in accordance with an embodiment of the present disclosure, the driving shafts can be precisely aligned and connected.

Further, in accordance with an embodiment of the present disclosure, the generation of particles in a process of connecting the driving shafts can be minimized.

It is natural that the scope of the present disclosure is not limited to these effects.

Although the present disclosure has been described with reference to embodiments shown in the drawings, the embodiments are provided as only exemplary examples, and those skilled in the art will understand that various modifications and equivalent other embodiments are possible therefrom. Therefore, the true technical protection scope of the present disclosure should be determined by the technical spirit of the appended claims.

[Description of Symbols]

10: substrate processing facility

100: index module

200: process processing module

240: transfer chamber

300: transfer plate, transfer plate set

310: first plate part

311: first base

320: first guide member

330: receiving part

337: fixing pin

350: second plate part

351: second base

360: second guide member

370: insertion part

375: first protrusions

376: second protrusions

377: fixture

400: substrate transfer unit

What is claimed is:

1. A transfer plate set for guiding a substrate transfer unit to move, the transfer plate set comprising:
a first plate part; and
a second plate part inserted into and fixed to the first plate part,
wherein the first plate part comprises:
a first base;
a first guide member disposed on the first base; and
a receiving part formed to have a stepped portion at a first side of the first base, the first side being adjacent to the second plate part, wherein the second plate part comprises:
a second base;
a second guide member disposed on the second base; and
an insertion part formed to protrude from a second side of the second base in a first horizontal direction, the second side being adjacent to the first plate part, and wherein the insertion part is inserted into the receiving part.

2. The transfer plate set according to claim 1,
wherein upper and lower surfaces of the insertion part extend in the first horizontal direction and are spaced apart from each other in a vertical direction that is perpendicular to the first horizontal direction.

3. The transfer plate set according to claim 2,
wherein the insertion part includes first protrusions that protrudes from upper and lower surfaces of the insertion part in the vertical direction, respectively.

4. The transfer plate set according to claim 3,
wherein corners of the first protrusions is rounded.

5. The transfer plate set according to claim 4,
wherein each of the first protrusions extends lengthwise in a second horizontal direction that is perpendicular to the first horizontal direction and the vertical direction.

6. The transfer plate set according to claim 3,
wherein a sum of a distance, in the vertical direction, between the lower and upper surfaces of the insertion part and heights, in the vertical direction, of the first protrusions corresponds to a height, in the vertical direction, of the stepped portion of the receiving part.

7. The transfer plate set according to claim 2,
wherein the insertion part further includes two opposite side surfaces spaced apart from each other in a second horizontal direction that are perpendicular to the first horizontal direction and the vertical direction, and
wherein the insertion part further includes second protrusions that protrude from the opposite side surfaces in the second horizontal direction, respectively.

8. The transfer plate set according to claim 7,
wherein corners of the second protrusions are rounded.

9. The transfer plate set according to claim 8,
wherein the second protrusions rotatably contact the stepped portion of the receiving part and extends in the vertical direction.

10. The transfer plate set according to claim 1,
wherein the insertion part, when viewed in a plan view, has a shape in which a width of the insertion part gradually increases to a maximum width of the insertion part and then gradually decreases from the maximum width of the insertion part in a direction away from the second side of the second base,
wherein the maximum width of the insertion part corresponds to a width of the receiving part, and
wherein the width of the insertion part and the width of the receiving part are measured in a second horizontal direction that is perpendicular to the first horizontal direction.

11. The transfer plate set according to claim 1,
wherein the second plate part further includes a fixture that penetrates the insertion part in a thickness direction of the second plate part.

12. The transfer plate set according to claim 11,
wherein the first plate part further includes a fixing pin that is installed at the receiving part,
wherein at least a portion of the fixing pin of the first plate part is engaged with the fixture of the second plate part, and
wherein the fixture has a size equal to or larger than the fixing pin, and
wherein, when the insertion part is inserted into the receiving part, at least a portion of the fixing pin enters the fixture.

13. The transfer plate set according to claim 1,
wherein the second plate part further includes connecting holes that penetrate the insertion part in a thickness direction of the second plate part,
wherein the first plate part further includes fastening grooves that are formed at the receiving part, and
wherein the connecting holes and the fastening grooves are engaged with each other.

14. The transfer plate set according to claim 3,
wherein the stepped portion of the receiving part and the first protrusions of the insertion part are configured such that, when the insertion part is inserted into the stepped portion of the receiving part, the receiving part and the first protrusions of the insertion part rotatably contact with each other at a point or at a line.

15. The transfer plate set according to claim 14,
wherein the first plate part further comprises a cover part for covering the stepped portion of the receiving part,
wherein the insertion part is disposed in an insertion space formed by the stepped portion of the receiving part and the cover part, and
wherein a rotational pitch PI in the vertical direction of the insertion part is controlled by a height difference between each of the upper and lower surfaces of the insertion part and a corresponding one of the first protrusions in a process in which the insertion part is inserted into the receiving part.

16. The transfer plate set according to claim 7,
wherein the stepped portion of the receiving part and the second protrusions of the insertion part are configured such that the second protrusions of the insertion part rotatably contact opposite side surfaces, in the second horizontal direction, of the stepped portion of the receiving part at a point or a line, respectively.

17. The transfer plate set according to claim 16,
wherein a rotational yaw of the insertion part around vertical vertical direction is controlled by a difference between a width of an end of the insertion part and a width of the second protrusions in a process in which the insertion part is inserted into the receiving part.

18. A substrate transfer apparatus, comprising:
a transfer chamber to which at least one substrate processing apparatus for processing a substrate is coupled;
a substrate transfer unit installed inside the transfer chamber and configured to support a substrate to load or unload the substrate into or from the substrate processing apparatus; and
a transfer plate configured to guide the substrate transfer unit to move inside the transfer chamber,
wherein the transfer plate comprises a first plate part; and a second plate part inserted and fixed to the first plate part,
wherein the first plate part comprises a first guide member disposed on the first plate part; and a receiving part formed to be stepped on a side facing the second plate part,
wherein the second plate part comprises a second guide member disposed on the second plate part; and an insertion part formed to protrude from a side facing the first plate part and provided to be inserted into the receiving part,
wherein first protrusions are formed on upper and lower surfaces of the insertion part, and second protrusions are formed on left and right surfaces with respect to a longitudinal direction of the insertion part, and
wherein the substrate transfer unit is installed to be movable along the first guide member and the second guide member.

19. The substrate transfer apparatus according to claim 18,
wherein an upper part of the receiving part is covered by a cover part,
wherein a sum of a height of the insertion part and heights of the first protrusions corresponds to a height of the receiving part, and
wherein, when the insertion part is inserted and fixed to the receiving part, the insertion part is disposed in an insertion space formed by a step of the receiving part and the cover part.

20. A transfer plate set for manufacturing a transfer plate, the transfer plate set guiding a substrate transfer unit for loading or unloading a substrate into or from a substrate processing apparatus to move,
wherein the transfer plate set comprises a first plate part; and a second plate part inserted and fixed to the first plate part,
wherein the first plate part comprises a first guide member disposed on the first plate part;
and a receiving part formed to be stepped on a side facing the second plate part,
wherein the second plate part comprises a second guide member disposed on the second plate part; and an insertion part formed to protrude from a side facing the first plate part and provided to be inserted into the receiving part,
wherein first protrusions having rounded corners are formed on upper and lower surfaces of the insertion part, and second protrusions having rounded corners are formed on left and right surfaces with respect to a longitudinal direction of the insertion part,
wherein a sum of a height of the insertion part and heights of the first protrusions corresponds to a height of the receiving part, and
wherein when the insertion part is inserted and fixed to the receiving part, the receiving part and the first protrusions of the insertion part come into point contact or line contact, a side surface of the receiving part and the second protrusions of the insertion part come into point contact or line contact, and the first guide member of the first plate part and the second guide member of the second plate part are aligned on the same axis.
